(19) United States
(12) Patent Application Publication
(10) Pub. No.: US 2010/0319757 A1
(43) Pub. Date: Dec. 23, 2010

(54) METHODS AND DEVICES FOR AN ELECTRICALLY NON-RESISTIVE LAYER FORMED FROM AN ELECTRICALLY INSULATING MATERIAL

(76) Inventor: Wolf Oetting, San Jose, CA (US)

Correspondence Address: Director of IP, 5521 Hellyer Avenue, San Jose, CA, 95138, US

(21) Appl. No.: 12/767,787

(22) Filed: Apr. 26, 2010

Related U.S. Application Data
(60) Provisional application No. 61/172,357, filed on Apr. 24, 2009.
(60) Provisional application No. 61/185,559, filed on Jun. 9, 2009.

(51) Int. Cl. H01L 31/04; H01L 31/18

(52) U.S. Cl. 136/252; 427/74

(57) ABSTRACT

A method is described that provides a current carrying substrate and individually controlling film characteristics for a material being simultaneously formed on both sides of the substrate so as to provide a first layer of the material on one side substantially thicker than a second layer on another side of the substrate. The thinned layer is formed from an electrically insulating material but is configured such that the layer provides no significant electrical resistance to current passing through the layer.

### CROSS REFERENCE TO RELATED APPLICATIONS

This application claims priority to U.S. Provisional Application Ser. No. 61/172,357 filed Apr. 24, 2009 and U.S. Provisional Application Ser. No. 61/185,559 filed Jun. 9, 2009. All above applications are fully incorporated herein by reference for all purposes.

### FIELD OF THE INVENTION

The present invention relates to electrically conductive layer(s) and more specifically to electrically conductive layer(s) for photovoltaic devices.

### BACKGROUND OF THE INVENTION

To improve solar cell performance and reduce the cost of solar cell production, it would be desirable to fabricate a photovoltaic absorber layer on a substrate that is relatively inexpensive, lightweight, and flexible. One substrate that could fall into this category is aluminum foil. Unfortunately despite its lower cost, aluminum foil presents many challenges to those attempting to use it as a substrate for solar cell fabrication. Aluminum is generally regarded by the industry as unsuitable for solar cells production using known techniques due in part to is properties under temperature (CTE). For example, some known photovoltaic absorber deposition techniques include evaporation, sputtering, chemical vapor deposition, and the like. These deposition processes are typically carried out at high temperatures and for extended times. Both factors can result in damage to the aluminum substrate upon which deposition is occurring. Such damage can arise directly from changes in the substrate material upon exposure to heat and/or from undesirable chemical reactions driven by the heat of the deposition process. Thus, very robust substrate materials are typically used for fabrication of thin film solar cells. In the past, these limitations have excluded the use of aluminum and aluminum-foil based foils.

Furthermore, there are several factors that result in Al substrate degradation when used in the formation of solar cells based on CIGS. First, upon extended heating, the discrete layers within a Mo-coated Al substrate can fuse and form an intermetallic back contact for the device, which decreases the intended electronic functionality of the Mo-layer. Second, the interfacial morphology of the Mo layer is altered during heating, which can negatively affect subsequent CIGS grain growth through changes in the nucleation patterns that arise on the Mo layer surface. Third, upon extended heating, Al can migrate into the CIGS absorber layer, disrupting the function of the semiconductor. Fourth, the impurities that are typically present in the Al foil (e.g. Si, Fe, Mn, Ti, Zn, and V) can travel along with mobile Al that diffuses into the solar cell upon extended heating, which can disrupt both the electronic and optoelectronic function of the cell. Fifth, when Se is exposed to Al for relatively long times and at relatively high temperatures, aluminum selenide can form, which is unstable. In moist air the aluminum selenide can react with water vapor to form aluminum oxide and hydrogen selenide. Hydrogen selenide is a highly toxic gas, whose free formation can pose a safety hazard. For all these reasons, high-temperature deposition, annealing, and selenization are therefore impractical for substrates made of aluminum or aluminum alloys.

To address some of these challenges, techniques have been used to provide various types of protective layer(s) on the aluminum foil. Unfortunately, these techniques typically interfere with or significantly degrade some of the advantages of the aluminum foil as a substrate. For example, the cost of some of these protective layers is prohibitive relative to the low cost of the aluminum foil. Thus, although it may be possible to provide protection by depositing a variety of other layers over the aluminum foil, the cost associated with these additional steps and the material cost associated with some exotic protective layers diminishes the cost advantage of using aluminum foil. Furthermore, the aluminum foil substrate may be used as a charge carrier in some solar cell configurations, and this is particularly advantageous in solar cell configurations using a back-side contacted design wherein the large area provided by the substrate allows for more current to be carried than charge carriers or bus bars on the front side of the cell. The ability of the aluminum foil to be a charge carrier for the solar cell, however, is negatively impacted by some protective layers that may be used on the aluminum foil substrate. These protective materials are sometimes formed from electrically insulating materials. Although additional processing steps can be implemented to mitigate this issue, the additional steps come at a material cost and/or tooling cost that diminishes the low cost advantage of the aluminum foil as a substrate.

Thus, there is a need in the art for improved substrates and material layers for use in fabricating solar cells.

### SUMMARY OF THE INVENTION

The disadvantages associated with the prior art are overcome by at least some embodiments of the present invention. Embodiments of the invention were conceived in response to a failure of traditional protective layers to meet a low cost, high throughput processing environment. It should be understood that the process steps herein and/or the protective layer are applicable to an electrically conductive metal substrate which may be flexible or rigid. It should also be understood that some embodiments herein are applicable to electrically conductive metals which can be anodized. It should also be understood that the embodiments herein are applicable to substrate used in other industries and not limited to application in photovoltaic devices.

In one embodiment of the present invention, a system is provide for how to use a reel to reel anodizing process to control film thickness and morphology of alumina films for both sides of an aluminum foil substrate. It should be understood that formation of alumina on one side does not interfere with the electrical conductivity of the other side of the substrate. In some embodiments, it may be electrically conductive without further doping, sputtering, layering, or treatment with an electrically conductive material.

A further understanding of the nature and advantages of the invention will become apparent by reference to the remaining portions of the specification and drawings.

### BRIEF DESCRIPTION OF THE DRAWINGS

FIGS. 1A-1E show side cross-sectional views of various embodiments of the present invention.

FIG. 2 shows another cross-sectional view of one embodiment of the present invention.

FIG. 3 shows another cross-sectional view of one embodiment of the present invention.

FIG. 4 shows another cross-sectional view of one embodiment of the present invention.

FIG. 5 shows a schematic for forming an anodized layer according to one embodiment of the present invention.

FIGS. 6 and 7 show side cross-sectional views of solar cells according to embodiments of the present invention.

FIGS. 8a and 8b show still further cross-sectional views of embodiments of the present invention.

### DESCRIPTION OF THE SPECIFIC EMBODIMENTS

It is to be understood that both the foregoing general description and the following detailed description are exemplary and explanatory only and are not restrictive of the invention, as claimed. It may be noted that, as used in the specification and the appended claims, the singular forms “a”, “an” and “the” include plural referents unless the context clearly dictates otherwise. Thus, for example, reference to “a material” may include mixtures of materials, reference to “a compound” may include multiple compounds, and the like. References cited herein are hereby incorporated by reference in their entirety, except to the extent that they conflict with teachings explicitly set forth in this specification.

In this specification and in the claims which follow, reference will be made to a number of terms which shall be defined to have the following meanings:

“Optional” or “optionally” means that the subsequently described circumstance may or may not occur, so that the description includes instances where the circumstance occurs and instances where it does not. For example, if a device optionally contains a feature for a barrier film, this means that the barrier film feature may or may not be present, and, thus, the description includes both structures wherein a device possesses the barrier film feature and structures wherein the barrier film feature is not present.

Embodiments of the present invention allow fabrication of thin film absorber layers such as but not limited to CIGS on aluminum foil substrates. According to embodiments of the present invention, a nascent absorber layer containing elements of group IB and IIIA formed on an aluminum substrate by solution deposition may be annealed by rapid heating from an ambient temperature to a plateau temperature range of between about 200° C. and about 600° C. The temperature is maintained in the plateau range for between about 0.1 minutes to about 15 minutes, and subsequently reduced. In another embodiment, the temperature is maintained in the plateau range for between about 0.1 minutes to about 5 minutes. In another embodiment, the temperature is maintained in the plateau range for between about 0.1 minutes to about 30 minutes. In another embodiment, the temperature is maintained in the plateau range for between about 0.1 minutes to about 60 minutes. Alternatively, the annealing temperature could be modulated to oscillate within a temperature range without being maintained at a particular plateau temperature.

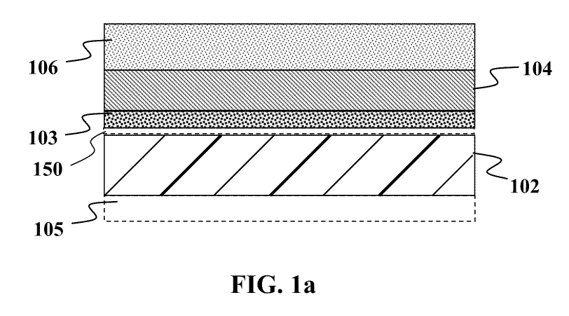

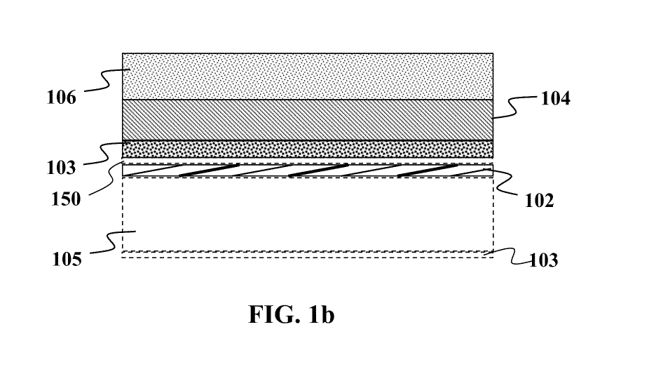

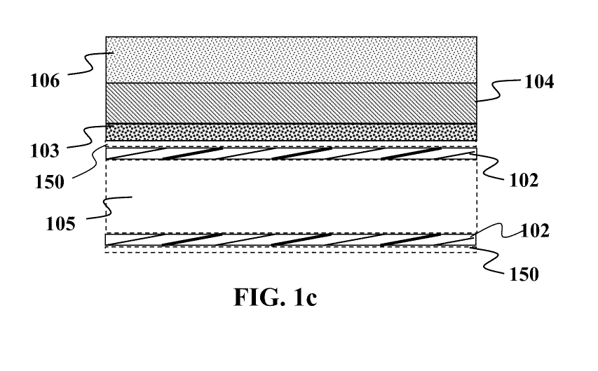

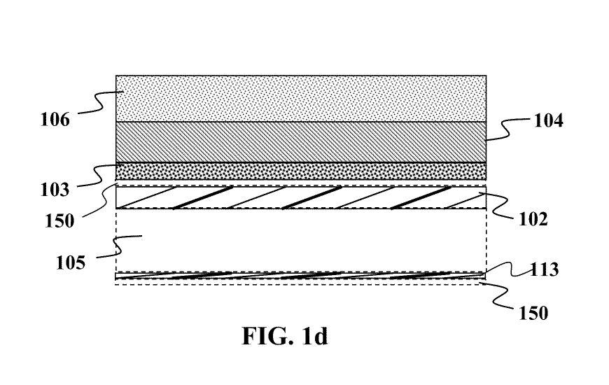

FIG. 1a depicts a partially fabricated photovoltaic device 100 generally including a substrate 102, an optional base electrode 104, and a nascent absorber layer 106. By way of non-limiting example, the substrate 102 may be made of a metal such as aluminum. In other embodiments, metals such as, but not limited to, stainless steel, molybdenum, titanium, copper, metallized plastic films, or combinations of the foregoing may be used as the substrate 102. Alternative substrates include but are not limited to ceramics, glasses, and the like. Any of these substrates may be in the form of foils, sheets, rolls, the like, or combinations thereof. Depending on the conditions of the surface, and material of the substrate, it may be useful to clean and/or smoothen the substrate surface. By way of nonlimiting example, the aluminum foil substrate 102 may be approximately 5 microns to one hundred or more microns thick and of any suitable width and length. The aluminum foil substrate 102 may be made of aluminum or an aluminum-based alloy.

Alternatively, the aluminum foil substrate 102 may be made by metallizing a polymer foil substrate, where the polymer is selected from the group of polyesters, polyethylene naphtalates, polyetherimides, polyethersulfones, polyetheretherketones, polyimides, and/or combinations of the above. By way of example, the substrate 102 may be in the form of a long sheet of aluminum foil suitable for processing in a roll-to-roll system. The base electrode 104 is made of an electrically conducive material compatible with processing of the nascent absorber layer 106. By way of example, the base electrode 104 may be a layer of molybdenum, e.g., about 0.01 to 5 microns thick, and optionally from about 0.1 to 1.0 microns thick. Optionally, in other embodiments, the base electrode 104 may be substantially thinner such as in the range of about 5 nm to about 100 nm, optionally 10 nm to 50 nm. These thinner electrodes 104 may be used with thicker layers of barrier layers 103. The base electrode layer may be deposited by sputtering or evaporation or, alternatively, by chemical vapor deposition (CVD), atomic layer deposition (ALD), sol-gel coating, electroplating and the like.

Optionally, it should also be understood that some substrates may comprise of aluminizing one or more sides of a non-aluminum substrate. Thus, some embodiments may have a core of stainless steel, carbon steel, molybdenum, titanium, copper, plastic films, ceramics, glasses, the like, or combinations of the foregoing may be used as the substrate 102. At least one side is aluminized with a layer of aluminum deposited using any of the vacuum and/or non-vacuum techniques described herein. Some embodiments may optionally aluminize both sides of the substrate. Still further, other embodiments may aluminize all sides of the substrate. The thickness of the aluminum layers are in aggregate, typically less than about 50% of the total thickness of the final substrate. Optionally, the thickness of the aluminum layers are in aggregate, typically less than about 40% of the total thickness of the final substrate. Optionally, the thickness of the aluminum layers are in aggregate, typically less than about 30% of the total thickness of the final substrate. Optionally, the thickness of the aluminum layers are in aggregate, typically less than about 20% of the total thickness of the final substrate. Optionally, the thickness of the aluminum layers are in aggregate, typically less than about 10% of the total thickness of the final substrate.

Optionally, it should also be understood that some substrates may comprise of metalizing (with an electrically conductive material such as but not limited to copper, silver, gold, etc. . . . ) one or more sides of a non-aluminum metallic substrate. Thus, some embodiments may have a core of stainless steel, carbon steel, molybdenum, titanium, copper, plastic films, ceramics, glasses, the like, or combinations of the foregoing may be used as the substrate 102. At least one side is metalized with a layer of said electrically conductive material deposited using any of the vacuum and/or non-vacuum techniques described herein. Some embodiments may optionally metalize both sides of the substrate with the same or different material. Still further, other embodiments may treat all sides of the substrate with an electrically conductive material. The thickness of the electrically conductive material layers are in aggregate, typically less than about 50% of the total thickness of the final substrate. Optionally, the thickness of the electrically conductive material layers are in aggregate, typically less than about 40% of the total thickness of the final substrate. Optionally, the thickness of the electrically conductive material layers are in aggregate, typically less than about 30% of the total thickness of the final substrate.

Optionally, the thickness of the electrically conductive material layers are in aggregate, typically less than about 20% of the total thickness of the final substrate. Optionally, the thickness of the electrically conductive material layers are in aggregate, typically less than about 10% of the total thickness of the final substrate.

### Front Side Protection

Aluminum and molybdenum can and often do inter-diffuse into one another, with deleterious electronic and/or optoelectronic effects on the device 100. To inhibit such inter-diffusion and provide protection to substrate 102, an intermediate, interfacial layer 103 may be incorporated between the aluminum foil substrate 102 and molybdenum base electrode 104. The interfacial layer may be composed of any of a variety of materials, including but not limited to chromium, vanadium, tungsten, and glass, or compounds such as nitrides (including but not limited to titanium nitride, tantalum nitride, tungsten nitride, hafnium nitride, niobium nitride, zirconium nitride vanadium nitride, silicon nitride, or molybdenum nitride), oxynitrides (including but not limited to oxynitrides of Ti, Ta, V, W, Si, Zr, Nb, Hf, or Mo), oxides (including but not limited to oxides of Ti, Ta, V, W, Si, Zr, Nb, Hf, or Mo), and/or carbides (including but not limited to carbides of Ti, Ta, V, W, Si, Zr, Nb, Hf, or Mo). The material may be selected to be an electrically conductive material. In one embodiment, the materials selected from the aforementioned may be those that are electrically conductive diffusion barriers. The thickness of this layer can range from 10 nm to 50 nm or from 10 nm to 30 nm. Optionally, the thickness may be in the range of about 50 nm to about 1000 nm. Optionally, the thickness may be in the range of about 100 nm to about 750 nm. Optionally, the thickness may be in the range of about 100 nm to about 500 nm. Optionally, the thickness may be in the range of about 110 nm to about 300 nm. In one embodiment, the thickness of the layer 103 is at least 100 nm or more. In another embodiment, the thickness of the layer 103 is at least 150 nm or more. In one embodiment, the thickness of the layer 103 is at least 200 nm or more. Some embodiments may use two or more layers 103 of different materials, such as but not limited to two nitrides, a nitride/a carbide, or other combinations of the foregoing materials, wherein one layer may be selected to improve backside reflectivity. The layer 103 can deposited using any of a variety of means including but not limited to sputtering, evaporation, CBD, electroplating, CVD, PVD, ALD, and the like

Optionally, some embodiments may include another layer such as but not limited to an aluminum layer above the layer 103 and below the base electrode layer 104. Optionally, instead of Al, this layer may be comprised of one or more of the following: Cr, Ti, Ta, V, W, Si, Zr, Nb, Hf, and/or Mo. Some may use one or more of the materials selected from the list for layer 103. This layer may be thicker than the layer 103. Optionally, it may be the same thickness or thinner than the layer 103. The thickness of this layer above the layer 103 and below the base electrode layer 104 can range from 10 nm to 50 nm or from 10 nm to 30 nm. Optionally, the thickness may be in the range of about 50 nm to about 1000 nm. Optionally, the thickness may be in the range of about 100 nm to about 750 nm. Optionally, the thickness may be in the range of about 100 nm to about 500 nm. Optionally, the thickness may be in the range of about 110 nm to about 300 nm. The layer 104 can be deposited using any of a variety of means including but not limited to sputtering, evaporation, CBD, electroplating, CVD, PVD, ALD, and the like

Optionally, some embodiments may include another layer 150 such as but not limited to an aluminum layer or an alumina layer above the substrate 102 and below the barrier layer 103. Optionally, instead of Al, this layer may be comprised of one or more of the following: Cr, Ti, Ta, V, W, Si, Zr, Nb, Hf, and/or Mo. Some may use one or more of the materials selected from the list for layer 103. This layer may be thicker than the layer 103. Optionally, it may be the same thickness or thinner than the layer 103. The thickness of this layer above the substrate 102 and below the barrier layer 103 can range from 10 nm to 150 nm, 50 to 100 nm, or from 10 nm to 50 nm. Optionally, the thickness may be in the range of about 50 nm to about 1000 nm. Optionally, the thickness may be in the range of about 100 nm to about 750 nm. Optionally, the thickness may be in the range of about 100 nm to about 500 nm. Optionally, the thickness may be in the range of about 110 nm to about 300 nm. If the layer 150 comprises of an alumina layer, the details of such a layer will be discussed in more detail.

It should be understood that any of the above layers (or other layers herein) may be deposited using known vacuum and/or non-vacuum techniques. Vacuum techniques sputtering, evaporation, CBD, electroplating, CVD, PVD, ALD, and the like. Non-vacuum techniques may include wet coating, spray coating, spin coating, doctor blade coating, contact printing, top feed reverse printing, bottom feed reverse printing, nozzle feed reverse printing, gravure printing, microgravure printing, reverse microgravure printing, comma direct printing, roller coating, slot die coating, meyerbar coating, lip direct coating, dual lip direct coating, capillary coating, ink jet printing, jet deposition, spray deposition, and the like, as well as combinations of the above and/or related technologies.

### Backside Protection

In addition to protecting a front side surface of the substrate 102, it should also be understood that a backside surface of the substrate 102 may also receive one or more protective layers. Without being limited to any one theory, in one embodiment, the back side layer protection is there to prevent mechanical damage (scratching, scoring, etc. . . . ) and/or chemical reaction of the exposed back side of the substrate 102 with processing gases or chemical associated with manufacturing a photovoltaic device.

For example, the layer 103 may be placed on one or optionally both sides of the aluminum foil 102 (shown in phantom in FIG. 1a). One the back side, the protective layer may be identified as layer 105. The layer 105 can be deposited using any of a variety of means including but not limited to sputtering, evaporation, CBD, electroplating, CVD, PVD, ALD, and the like. If there are layers on both sides of the aluminum foil 102, it should be understood that the protective layers may be of the same material, or they may optionally be different materials from the aforementioned materials. This may be comprised of a material such as but not limited to Cr, Ti, Ta, V, W, Si, Zr, Nb, Hf, and/or Mo or compounds such as nitrides (including tantalum nitride, tungsten nitride, titanium nitride, silicon nitride, zirconium nitride, and/or hafnium nitride), oxides (including but not limited to Al₂O₃ or SiO₂), carbides (including SiC), and/or any single or multiple combination of the foregoing. Some may use one or more of the materials selected from the list for layer 103. By way of example, the underside layer 105 may be about 0.1 to about 5 microns thick, and optionally from about 0.1 to 1.0 microns thick. Optionally, in other embodiments, the layer may be substantially thinner such as in the range of about 5 nm to about 100 nm. It may be porous, partially porous, or fully dense. In some embodiments, the back side alumina layer is porous at some or all areas like the front side. One desires the dense part for protection, the rest for stiffness. The porosity of the anodized portion is a function of the growth speed and layer thickness.

Referring now to FIG. 1b, this embodiment shows an embodiment wherein the thickness or the qualities of layer 105 predominates and the layer 102 is more of a surface or cladding on the layer 105. In this manner, layer 105 through its increased thickness and/or inherent material strength provides greater stiffness for the entire substrate at the peak plateau processing temperature. Layer 102 provides in one embodiment, greater material electrical conductivity than the layer 105. In this manner, the two layers have different material properties, with one providing greater mechanical strength for web widths from 0.5 meter to 3 meters at processing temperatures between 520 and 600 C, while the second layer provides higher electrical conductivity at normal operating condition temperatures for solar cells. In one nonlimiting example, the high electrical conductivity material comprises of aluminum while the layer of higher material strength is stainless steel. In one embodiment, the thickness is about 10-50% aluminum while the remainder is stainless steel. Optionally, the thickness is about 5-20% aluminum while the remainder is stainless steel. Optionally, the thickness is about 20-60% aluminum while the remainder is stainless steel. Optionally, the thickness is about 25-75% aluminum while the remainder is stainless steel. Optionally, the thickness is about 40-60% aluminum while the remainder is stainless steel. Optionally, the thickness is about 50-80% aluminum while the remainder is stainless steel. In one embodiment, the overall combined thickness of all layers is about 0.050 mm to 0.3 mm. Optionally, the overall combined thickness is about 0.080 mm to 0.2 mm. Optionally, the overall combined thickness is about 0.10 mm to 0.2 mm. Optionally, the overall combined thickness is about 0.10 mm to 0.4 mm.

In one embodiment, the process for manufacturing comprises a cladding process of depositing molten material between an upper surface of the substrate and a juxtaposed endless belt surface continuously moving in the direction of movement of the substrate and parallel thereto while laterally confining the molten material between said surfaces between a pair of sliding shoes, the inclination of said surfaces along said path being between 30° and 70° to the horizontal, said belt surface approaching said upper surface of the substrate strip at an upper end of said path to form a bank of said molten material at said upper end, said belt surface extending away from said upper surface of said substrate at a lower location along said path, said substrate continuing along said inclined path below said location. The process may include cooling the molten material between said surfaces along said path to apply the cladding layer of the material in solidified form to said surface of said substrate and bond said layer to said substrate.

Referring now to FIG. 1c, at still further embodiment of the present invention will now be described. This embodiment is similar to the one of FIG. 1b, except that the underside also includes a layer of aluminum 102 and optionally the layer 150. The thickness of layer of aluminum 102 on the underside may be the same, thinner, or optionally thicker than that of the top side layer 102. Many embodiments may have the layer thinner on the underside as a materials savings, but other thicknesses are not excluded. Optionally, instead of layer 150, some may use a layer 103 and/or 104 in place of layer 150 or optionally, in conjunction with the layer 150. If is used in conjunction with layer 150, many embodiments may places those layers below layer 150, though other configurations such as above, are not excluded.

Referring now to FIG. 1d, this embodiment shows that a thicker layer 102 of aluminum is used while a thinner layer 113 of aluminum is used on the underside. In one embodiment, the aluminum quality also differs as some embodiments do not use the back side layer 113 for carrying current, but is there merely to help in forming the layer 150 on the back side of the substrate. Optionally, the layer 113 does not exceed 70% of the thickness of layer 102. Optionally, the layer 113 does not exceed only 60% of the thickness of layer 102. Optionally, the layer 113 does not exceed only 50% of the thickness of layer 102. Optionally, the layer 113 does not exceed only 40% of the thickness of layer 102. Optionally, the layer 113 does not exceed only 30% of the thickness of layer 102. Optionally, the layer 113 does not exceed only 20% of the thickness of layer 102. Optionally, the layer 113 does not exceed only 10% of the thickness of layer 102.

Referring now to FIG. 1e, this embodiment shows an embodiment wherein the thickness of the layers 102 and 105 are much close in terms of relative thickness. FIG. 1e also shows that the backside protection may be by way of layer 103 and not the layer 150 used in other embodiments as no backside aluminum layer is used herein. Optionally, instead of an aluminum material for layer 102, some embodiments may use a copper, silver, gold, or other material (including their alloys) that have higher electrical conductivity than stainless steel.

It should be understood that any of the embodiments herein may be mechanically smoothed or chemically brightened to remove peaks from the layer 105 or after layer 102 is applied to reduce protrusions and pits, which may have originally have heights or depths in the range of 500-2000 nm, or even larger. Some embodiments may provide a flexible conductive substrate having a top surface including protruded surface portions and recessed surface portions;an electrically conductive buffer layer disposed on the top surface of the flexible conductive substrate, wherein the electrically conductive buffer layer is a high conducivity layer that substantially fills the recessed surface portions while partially exposing some of the protruded surface portions; a contact layer disposed on the buffer or filler layer and the some of the protruded surface portions so that the contact layer makes physical and electrical contact with the some of the protruded surface portions; and an absorber layer formed over the contact layer. Optionally, some embodiments of the contact layer comprises one of tungsten, tantalum, molybdenum, titanium, chromium, ruthenium, iridium and osmium. This may be true for any of the layers 104 herein. The high conductive layer can be deposited using any of a variety of means including but not limited to solution deposition, electroplating, sputtering, evaporation, CBD, electroplating, CVD, PVD, ALD, and the like, depending on whether a conformal or nonconformal layer is desired.

### Electrically Conductive Layer

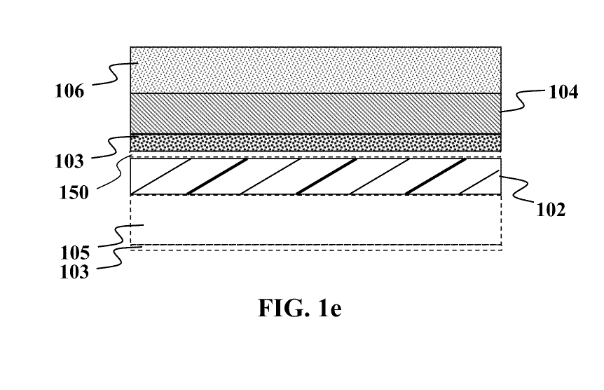

Referring now to FIG. 2, another embodiment of the present invention will now be described. This embodiment uses anodization to create one or more protective layers on the current carrying substrate. This protective layer maybe on the backside and/or the front side of the current carrying substrate. However, in forming the protective layer, the process typically simultaneously creates a layer of the same material on the other side of the substrate not directly targeted for treatment. This other layer is of the same material, but the deposition conditions may optionally be selective controlled to provide a different layer thickness, porosity, and/or configuration. In the case of anodization, this deposition or growth process creates an alumina layer on both sides of the substrate 102.

It should be understood that embodiments of the present invention is not limited to any one material such as alumina. Other types of materials such as but not limited to oxides of Cr, Ti, Ta, V, W, Si, Zr, Nb, Hf, and/or Mo may also be used. Some may use one or more of the materials selected from the list for layer 103.

The present embodiment of this invention comprises of an electrically conductive substrate 102 capable of carrying current and covered on both a top side and a bottom side with an electrically insulating material, wherein the material on one side of the substrate 102 is sufficiently thin so that charge can still pass through that layer and be carried by the substrate. Optionally, the material on this one side is only sufficiently thin at distributed and/or pre-selected locations over the layer while other areas of the layer are at greater thickness. In other words, the entire layer may itself have a greater maximum thickness while have a much lower minimum thickness at select areas. For example, the thinned areas may only be at the bottom of the pores. Optionally, there may be pre-selected areas such as but not limited to particular contact areas that are thinned, etched, or otherwise thickness-reduced during and/or after the deposition process. Such areas may be evenly distributed over the substrate, randomly distributed, or may be only at specific selected areas. Optionally, these thinned areas may be of any geometric shape such as but not limited to areas with outlines that are circular, hexagonal, polygonal, oval, other shaped, and/or single or multiple combinations of the foregoing.

Such a thin layer 150 comprised of an electrically insulating material, is found to be electrically conductive when configured as described herein. This is a surprising result as it was not expected to be electrically conductive. Typically, even a conventional 50 nm thick layer of alumina or similar electrically insulating material will provide sufficient electrical resistance so that the entire layer would be considered electrically insulating and provide a sufficiently high level of electrical resistance so as to substantially degrade solar cell performance. The embodiments herein, however, using a thin layer 150 provides solar cell performance equal to or in some cases better than otherwise identical solar cells without the thin layer 150 of electrically insulating material.

Referring still to FIG. 2, in this nonlimiting example, layers of electrically insulating material are formed on both sides of the substrate, but the side that is electrically conductive has a maximum thickness of no more than 50 nm. Optionally, the maximum thickness is about 60 nm or less. Optionally, the maximum thickness is about 70 nm or less. Optionally, the maximum thickness is about 100 nm or less. The layers 150 and 105 on the sides of the substrate 102 are typically simultaneously formed in the same process. This is advantageous in both reduction of processing steps and to improve processing throughput. Optionally, the layers 150 and 105 may be formed on their respective sides but at different rates. In one embodiment, the layer 150 is configured to include a plurality of pores. The morphology of the layer 150 may be such that it allows it to be not a resistor. The minimum thickness is determined by the bottom wall thickness of the pores. The control of the porosity may be in terms of pore size, edge-to-edge spacing between pores, and/or pore depth. By way of nonlimiting example, the embodiment described above may be configured to have other configurations. For example, the maximum thickness of layer 150 may be selected to between 5 to 100 nm. The porosity may be selected to be between about 10 to 70 nm pore size.

Optionally, FIG. 2 shows that the layer 150 may be subsequently filled with another material 152. In this particular embodiment, the material 152 is typically electrically conductive material, but other materials are not excluded. Some embodiments may use a semiconductor material. By way of nonlimiting example, the material 152 in conductive form may be a transition metal nitride, molybdenum, chromium, or the like. This material 152 applied to the pores may be by way of a vacuum deposition process. Optionally, the material 152 may be applied by a non-vacuum process such as solution deposition. The material 152 may partially fill the pores, fully fill the pores, or overfill the pores. Some embodiments may conformally coat the pores.

Some embodiments may optionally use a sputtering process for applying material 152 and/or additional material (on top and/or below material 152) as this process may preferentially provide additional stress on the thin layer 150 of electrically insulating material. The additional stress may be useful in providing deeper penetration of the material 152 into layer 150. Optionally, the sputtering may create cracks, pinholes, and/or defects in the thin layer while simultaneously depositing electrically conductive material into those cracks, pinholes, and/or defects in that thin layer 150. This may allow for greater penetration of an electrically conductive material into the thin layer 150 of electrically insulating material. Even though the thin layer 150 already provides negligible electrical resistance, this additional stress and electrically conductive material may provide improved pathways and charge carrying capacity.

Optionally, other vacuum based processes such as ALD may also be used to fill defects created by imparting additional stress on to the electrically insulating material. This vacuum deposition or other type of deposition may optionally occur after a stress creating step which may create the cracks, pinholes, and/or defects in thin layer 150. Optionally, the material 152 may be deposited without the stress inducing step.

Referring still to FIG. 2, the thickness of layer 105 on the underside of substrate 102 may be in the thickness range from about 500 to 5000 nm. In the present embodiment of the invention, this layer 105 comprises of the same material as used in layer 150. This is beneficial as it allows layers 103 and 150 to be formed at the same time. It should be understood however, that the features on each of these layers 103 and 150 may be individual controlled to due to substantial isolation of the processing conditions for the front side from the back side of the substrate. Some embodiments may use seals, substrate edge seals, masks, and/or shaped containers holding the bath 200 to allow further adjustment of the processing conditions for one side without impacting processing conditions on the other side, all the while having the substrate in the same bath or processing solution 200. The width of the substrate is not limited to any particular size and may be used with substrates of at least 100 mm, at least 300 mm, at least 500 mm, at least 750 mm, at least 1 m, or more in width. The thickness of the substrate may be at least 50 microns. Optionally, it may be at least 100 microns. Optionally, it may be at least 150 microns. Optionally, it may be at least 200 microns or more.

Although the substrate is described as comprising of aluminum, it should be understood that other materials may be used such as but not limited to alloys of aluminum, titanium or titanium alloys or other elements and alloys are also possible. Optionally some embodiments may use substrates that are combinations of material such as an embodiment having an aluminum upper surface, an aluminum bottom surface, and a central core comprised of a different material and/or alloy such as but not limited to steel, stainless steel, carbon steel, cooper, molybdenum, polyimide, or the like. By way of example, the metal layer over the core substrate may be Al metal (e.g., 99.99% pure) coated onto the metal core by use of evaporation, e-beam evaporation, sputtering, plating, ion-plating, liquid or gas-phase deposition, other plasma-assisted deposition methods, electro-deposition/plating, etc.; generally any technique that can produce uniform thin films of the desired metal or alloy such as aluminum. Others may optionally use Cr, Ti, Ta, V, W, Si, Zr, Nb, Hf, Mo, and/or the like.

### Pore Filling

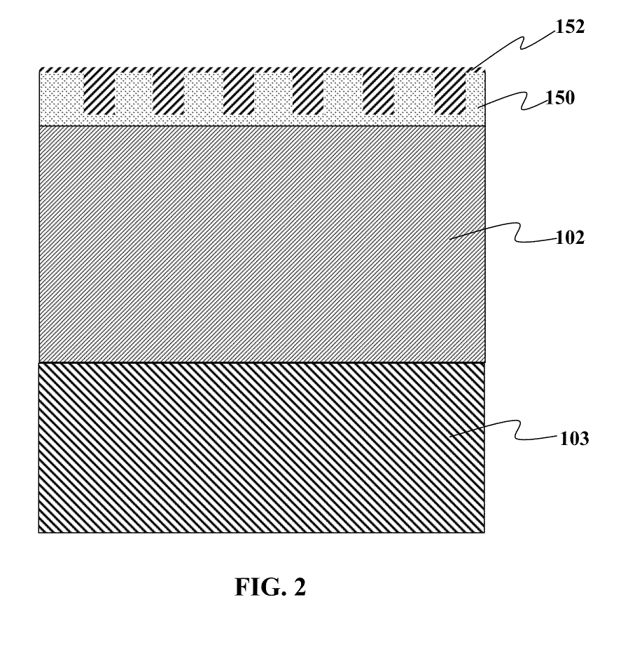

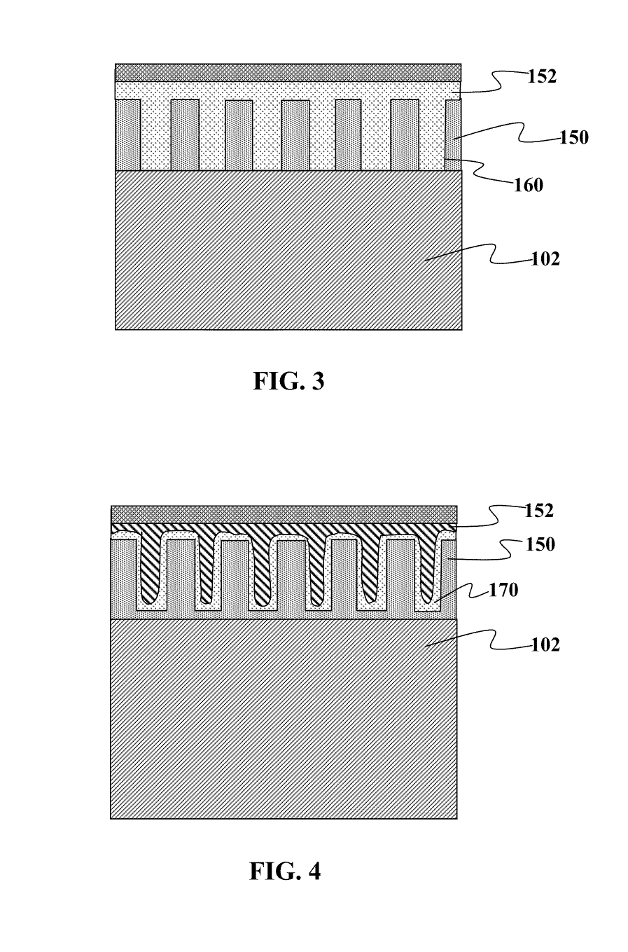

Referring now to FIGS. 3 and 4, other embodiments of the present invention are shown with pores filled with different materials and/or filled in different configurations. For example, FIG. 3 shows an embodiment wherein at least some of pores 160 extend completely through the thin layer 150. The pores 160 are filled with the material 152. As seen in FIG. 3, not only does this material 152 fill the pores 160, it also creates a substantially continuous or interconnected layer above the level of the pores 160. This configuration for the material 152 above the pores may also be applicable to any of the embodiments herein, including those where the thin layer 150 has pores that do not extend all the way through to the substrate 102.

FIG. 4 shows a still further embodiment wherein there is an interlayer 170 deposited into the pores. As seen in FIG. 4, this interlayer 170 may not completely fill those pores. In one embodiment, the interlayer 170 may be a conformal layer as shown in FIG. 4. Optionally, the layer 170 may be a layer that fills or substantially fills the pores. The material used in layer 170 when transparent may also be effective as an anti-reflective chamber. Optionally, some embodiments may use a transparent material for layer 150 and this may also provide an anti-reflective chamber, trapping light therein.

### Manufacturing

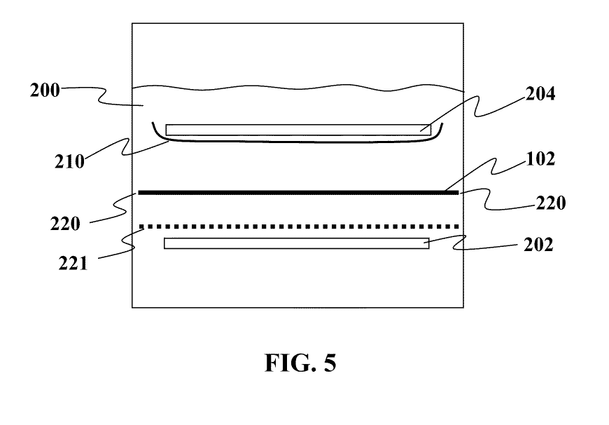

Referring now to FIG. 5, one embodiment of equipment for use in forming these layers will now be described. FIG. 5 show one embodiment of a manufacturing process that allows for individual control of the two layers simultaneously formed on both sides of the substrate. As seen in FIG. 5, the substrate 102 is placed in a bath 200 of electrolyte or other suitable liquid for deposition and/or growth the layers on both sides of the substrate. In a reel-to-reel or roll-to-roll process, the substrate can be moved a constant and/or variable speed through the bath 200. In the present embodiment, the bath 200 is sufficient in depth to contain the substrate 102, a first cathode 202, and a second cathode 204. This embodiment of the process will form layers of the same material on both sides of the substrate 102 while substrate 102 is in the bath.

Individual control of the processing conditions on each side of the substrate may be embodied by various mechanisms. For example, a shield 210 may be included over the cathode 204 so that its influence on the growth of layer on the top side of the substrate 102 is limited. Optionally, a shield (not shown) may also be used on cathode 202 if it is desirable to control the processing conditions for the back side of the substrate. In one embodiment, this shield 210 is configured to minimize the amount of material that is deposited on the non-targeted side of the substrate. In some embodiment, the shield 210 may be configured to bend around the cathode as shown in FIG. 5. Other embodiments may be straight without the bend. The material used for the shield may be any sacrificial anode material. Optionally, some embodiments may simply use different distances between frontside and back side cathode can be used to control process on both sides. Thus, by being closer to the backside cathode rather than the frontside cathode or vice versa, one can vary the thickness of layer on each side of the foil. For example as seen in FIG. 5 at position 221, the metal foil may be much closer to one cathode than the other cathode.

Another mechanism for controlling process conditions is proper sizing of the substrate 102 and the container holding the bath 200. This embodiment shown in FIG. 5 shows that the distance between the wall container holding bath 200 and the edge 220 of the substrate is minimized. This may be accomplished by changing the size of the substrate, the size of the bath container, or by introducing fins or geometric forms on the bath container to reduce the gap to the substrate. There will always be some electrically current that wraps around the edges of the substrate from one side to the other. The highest current may be along these edges. The close proximity of the edge 220 to the wall of the bath container will reduce the amount of eddy current lines that will curl around and reach the front side surface of the substrate 102. By way of nonlimiting example, this close proximity may be 3 inches or less along each edge for a substrate 750 mm wide. Optionally, other embodiments may mask the front side completely or at selected areas to allow for selective control of the deposition of material.

Anodization techniques for forming porous layers with nanometer scale pores are described e.g., in commonly assigned U.S. patent application Ser. No. 10/443,456 which is fully incorporated herein by reference for all purposes. For some applications, it is often desirable that the pores be approximately 1 nm to 100 nm in diameter with a pore density between about 10¹² pores per square meter to about 10¹⁶ pores per square meter. In some embodiment, the pores can reach all the way to the substrate 102. Alternatively, a layer of anodized metal can remain at the bottoms of the pores 112 so that the pores do not extend to the substrate and have a minimum bottom wall thickness. In one embodiment, the bottom wall thickness may be about 10 nm or less, while the entire layer thickness may be 30 nm to 300 nm in thickness. Optionally, some embodiments can have a bottom wall thickness of about 5 nm and an overall layer thickness of about 30 nm to 200 nm in thickness. Optionally, some embodiments can have a bottom wall thickness of about 15 nm and an overall layer thickness of about 30 nm to 300 nm in thickness. Optionally, some embodiments can have a bottom wall thickness of about 10 nm and an overall layer thickness of about 50 nm to 200 nm in thickness. Optionally, some embodiments can have a bottom wall thickness of about 15 nm and an overall layer thickness of about 70 nm to 200 nm in thickness.

This overall layer thickness process greater strength while providing sufficient barrier quality to minimize chemical interaction for the 5-10 minutes of heating over 500 C during processing in process gas. Optionally, in another embodiment, the overall layer thickness process greater strength while providing sufficient barrier quality to minimize chemical interaction for the 10-20 minutes of heating over 500 C during processing in process gas. In one embodiment, the imperfect barrier is provided so long as it provides sufficient protection for the times above during processing at processing temperature.

Referring now to FIGS. 8a and 8b, in one embodiment, the aspect ratio of bottom wall thickness to overall layer thickness of layer 150, which may be a porous oxide layer with a nonporous bottom wall, is in the range of about 1:20 to 1:5. Optionally, some embodiments may have it in the range of about 3:5 to about 3:20. The barrier layer thickness 800 may be in the range of about 5-30 nm in one embodiment, optionally, 5-20 nm, optionally 5-10 nm. Some may optionally go thinner than 5 nm. The pore size 802 can be selected to between 5 to 100 nm. The porosity may be selected to be between about 10 to 70 nm pore diameter. Optoinally, anodized layer thickness 804 can be from 20 nm to 300 nm, although in some embodiments, thicker is not excluded so long as the bottom wall thickness is in the range of 5 to 30 nm. Optionally, interpore distance 806 can be between 50 to 1000 nm, although greater is not excluded. Wall thickness 808 is based on the pore diameter and the interpore distances recited above.

FIG. 8b shows that in some embodiments having high aspect ratio of bottom wall thickness to anodized layer thickness of 1:7 to 1:20 or more can increase the ability of the layer to withstand bending stress during the addition of layer 103 or 104, as indicated by curved phantom lines 821 and 823 showing bending ability.

Optionally, without being limited to any one theory, the bottom wall includes cracks that may occur during processing, but they are sufficiently small and some may be filled with conductive material from layer 103 that they do not provide a sufficient pathway for chemical interdiffusion but still provide an electrical pathway through the bottom wall of the layer 150.

By way of nonlimiting example, an aluminum metal layer 102 can be anodized by treatment at 160V for a specified time, e.g., on the order of several minutes, in 5-10% H₃PO₄ below 10° C. The potential voltage can range from about 0.001V to about 250V. Optionally once the anodization is complete, one way, among others, to generate a perforated bottom at the base of the pores, is to step down the anodizing voltage, e.g., from 160V to 0.1 V in increments of about 0.3V or about 5% of the existing voltage, whichever is greater. The preceding protocol can result in a porous alumina layer with pores in the diameter range of about below 10 to about 450 nm. To further widen the pores, anodized specimens can be immersed, for example, in a 5% (vol) phosphoric acid solution at 30° C. for 5-60 min, both to enlarge the pore size and to remove the typical barrier layer found on most anodic alumina films. Typically, after anodization, there is a coating step to fill the pores in the thin layer 150. In this embodiment of the invention, this pore filling step is skipped and the pores remain open after the anodization step.

It should also be understood that porosity can be changed by electrolyte s well. For example, one can use H₂SO₄ instead of phosphoric acid and others are not excluded. In one example, the processing conditions are about 10 m/min, 170 F; in one embodiment, the present embodiment uses a relatively high voltage.

In a still further embodiment, the method may include a preclean stage using 70-80 F with alcaline cleaner having a ph in the range of about 6.5 to 10. Some embodiments may use a pre-etch. Optionally, some embodiments may exclude such a pre-etch use a rinse instead. Anodization in one embodiment uses sulphuric acid pH. 0.5-1.5, 10-20 A/ft2, 65-80 F, Al content<40 g/l. Some embodiments may use a nitric acid de-smut. Optionally, some use no de-smut step as this would widen the pores in the layer. Some embodiments may use a sealing step (normally boiling in water). Optionally, some embodiments do not use this sealing step as this would close the pores with hydroxides. The process may include a rinse and dry step using heated DI water-rinse at 140-160 F. Airknife+IR heat can be used to finish the drying.

In a still further embodiment, the method may include a preclean stage using 70-80 F with alcaline cleaner having a ph in the range of about 7.5 to 10. A rinse step is used after the pre-clean. Anodization in one embodiment uses sulphuric acid pH. 0.5-1.5, 10-20 A/ft2, 65-80 F, Al content<40 g/l. No de-smut step is used as this would widen the pores in the layer. No boiling in water is used as this sealing step as this would close the pores with hydroxides. The process may include a rinse and dry step using heated DI water-rinse at 140-160 F. Airknife+IR heat can be used to finish the drying.

In a still further embodiment, the method may include a preclean stage using 70-80 F with alcaline cleaner having a ph in the range of about 7.5 to 10. Some embodiments may use a pre-etch. Anodization in one embodiment uses H₃PO₄, pH. 0.5-1.5, 10-20 A/ft2, 65-80 F, Al content<40 g/l. Some embodiments may use a nitric acid de-smut. Optionally, some use no de-smut step as this would widen the pores in the layer. No sealing step is used as this would close the pores with hydroxides. The process may include a rinse and dry step using heated DI water-rinse at 140-160 F. Airknife+IR heat can be used to finish the drying.

### Barrier Properties

Optionally, it should be understood that the layer 150 can provide diffusion barrier properties, despite the relatively low minimum thickness of the layer 150. In one example, if the layer 150 comprises of 50 nm of alumina, the layer can provide a diffusion barrier against at least aluminum and iron. The barrier properties of the layer 150 is mainly required when the substrate 102 is heated during processing to temperatures above 100 degrees C. The longer that the substrate 102 remains at elevated temperatures, the thicker the layer 150 should be. In the current embodiment, the layer 150 at a thickness of 50 nm is sufficient to resist maximum temperatures of 525 degrees C. for a period of time not to exceed 20 minutes. Optionally, the layer 150 at a thickness of 50 nm is sufficient to resist maximum temperatures of 500 degrees C. for a period of time not to exceed 30 minutes. Of course, these examples are purely exemplary and are not limiting.

Optionally, instead of completely replacing a barrier layer, the layer 150 may be used with a thinner layer of diffusion barrier material. Such diffusion barrier materials were previously recited above in regards to layer 103. The reduced thickness may be in the range of less than 1 micron. Optionally, the reduced thickness may be less than 500 nm. Optionally, the reduced thickness may be less than 400 nm. Optionally, the reduced thickness may be less than 300 nm. Optionally, the reduced thickness may be less than 200 nm. Optionally, the reduced thickness may be less than 100 nm. Optionally, the reduced thickness may be less than 500 nm. One embodiment of the present invention may completely remove Ti and TiN as a layer, which may provide cost reduction due to removal of the layer.

### High Efficiency Cell Configuration

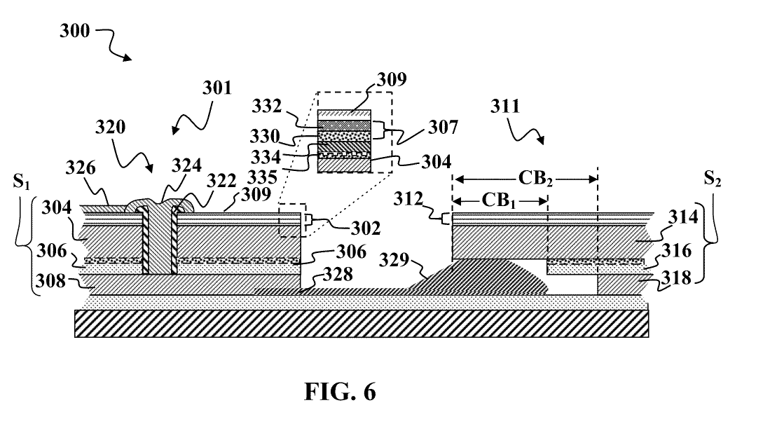

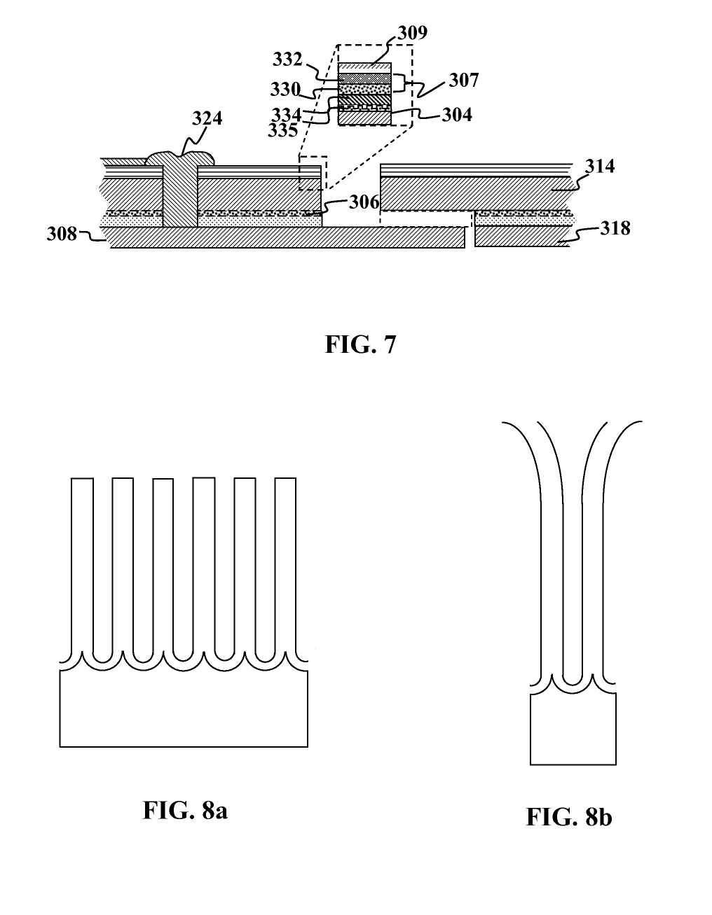

It should be understood that the device manufactured as shown in FIG. 1 and the above paragraphs may be suitable for use in a high efficiency cell configuration as detailed below in FIGS. 6 and 7. The use of an electrically non-resistive layer 150 (now identified as layer 335 in FIGS. 6 and 7) is desirable so that electrical current can be carried through layer 304.

FIG. 6 illustrates an array 300 of optoelectronic devices according to an embodiment of the present invention. In some embodiments, this may be considered a series interconnection in an array 300 of optoelectronic devices. The array 300 includes a first device module 301 and a second device module 311. The device modules 301, 311 may be photovoltaic devices, such as solar cells, or light-emitting devices, such as light-emitting diodes. In a preferred embodiment, the device modules 301, 311 are solar cells. The first and second device modules 301, 311 are attached to an insulating carrier substrate 303, which may be made of a plastic material such as polyethylene terephthalate (PET), e.g., about 50 microns thick. The carrier substrate 303 may, in turn, be attached to a thicker structural membrane 305, e.g., made of a polymeric roofing membrane material such as thermoplastic polyolefin (TPO) or ethylene propylene diene monomer (EPDM), to facilitate installing the array 300 on an outdoor location such as a roof.

By way of nonlimiting example, the device modules 301, 311, which may be about 4 inches in length and 12 inches wide, may be cut from a much longer sheet containing several layers that are laminated together. Each device module 301, 311 generally includes a device layer 302, 312 in contact with a bottom electrode 304, 314 and an insulating layer 306, 316 between the bottom electrode 304, 314 and a conductive back plane 308, 318. It should be understood that in some embodiments of the present invention, the back plane 308, 318 may be described as a backside top electrode 308, 318. The bottom electrodes 304, 314, insulating layers 306, 316 and back planes 308, 318 for substrates S₁, S₂ support the device layers 302, 312

In contrast to prior art cells, where the substrates are formed by depositing thin metal layers on an insulating substrate, embodiments of the present invention utilize substrates S₁, S₂ based on flexible bulk conducting materials, such as foils. Although bulk materials such as foils are thicker than prior art vacuum deposited metal layers they can also be cheaper, more readily available and easier to work with. Preferably, at least the bottom electrode 304, 314 is made of a metal foil, such as aluminum foil. Alternatively, copper, stainless steel, titanium, molybdenum or other suitable metal foils may be used. By way of example, the bottom electrodes 304, 314 and back planes 308, 318 may be made of aluminum foil about 1 micron to about 200 microns thick, preferably about 25 microns to about 100 microns thick; the insulating layers 306, 316 may be made of a plastic foil material, such as polyethylene terephthalate (PET) about 1 micron to about 200 microns thick, preferably about 10 microns to about 50 microns thick. In one embodiment, among others, the bottom electrode 304,114, insulating layer 306, 316 and back plane 308, 318 are laminated together to form the starting substrates S₁, S₂. Although foils may be used for both the bottom electrode 304, 314 and the back plane 308, 318 it is also possible to use a mesh grid on the back of the insulating layer 306, 316 as a back plane. Such a grid may be printed onto the back of the insulating layer 306, 316 using a conductive ink or paint. One example, among others, of a suitable conductive paint or ink is Dow Corning® PI-2000 Highly Conductive Silver Ink available from Dow Corning Corporation of Midland Mich. Dow Corning® is a registered trademark of Dow Corning Corporation of Midland Mich. Furthermore, the insulating layer 306, 316 may be formed by anodizing a surface of a foil used for the bottom electrode 304, 314 or back plane 308, 318 or both, or by applying an insulating coating by spraying, coating, or printing techniques known in the art.

The device layers 302, 312 generally include an active layer 307 disposed between a transparent conductive layer 309 and the bottom electrode 304. By way of example, the device layers 302, 312 may be about 2 microns thick. At least the first device 301 includes one or more electrical contacts 320 between the transparent conducting layer 309 and the back plane 308. The electrical contacts 320 are formed through the transparent conducting layer 309, the active layer 307, the bottom electrode 304 and the insulating layer 306. The electrical contacts 320 provide an electrically conductive path between the transparent conducting layer 309 and the back plane 308. The electrical contacts 320 are electrically isolated from the active layer 307, the bottom electrode 304 and the insulating layer 306.

The contacts 320 may each include a via formed through the active layer 307, the transparent conducting layer 309, the bottom electrode 304 and the insulating layer 306. Each via may be about 0.1 millimeters to about 1.5 millimeters, preferably 0.5 millimeters to about 1 millimeter in diameter. The vias may be formed by punching or by drilling, for example by mechanical, laser or electron beam drilling, or by a combination of these techniques. An insulating material 322 coats sidewalls of the via such that a channel is formed through the insulating material 322 to the back plane 308. The insulating material 322 may have a thickness between about 1 micron and about 200 microns, preferably between about 10 microns and about 200 microns.

The insulating material 322 should preferably be at least 10 microns thick to ensure complete coverage of the exposed conductive surfaces behind it. The insulating material 322 may be formed by a variety of printing techniques, including for example inkjet printing or dispensing through an annular nozzle. A plug 324 made of an electrically conductive material at least partially fills the channel and makes electrical contact between the transparent conducting layer 309 and the back plane 308. The electrically conductive material may similarly be printed. A suitable material and method, for example, is inkjet printing of solder (called “solderjet” by Microfab, Inc., Plano, Tex., which sells equipment useful for this purpose). Printing of conductive adhesive materials known in the art for electronics packaging may also be used, provided time is allowed subsequently for solvent removal and curing. The plug 324 may have a diameter between about 5 microns and about 500 microns, preferably between about 25 and about 100 microns.

By way of nonlimiting example, in other embodiments, the device layers 302, 312 may be about 2 microns thick, the bottom electrodes 304, 314 may be made of aluminum foil about 100 microns thick; the insulating layers 306, 316 may be made of a plastic material, such as polyethylene terephthalate (PET) about 25 microns thick; and the backside top electrodes 308, 318 may be made of aluminum foil about 25 microns thick. The device layers 302, 312 may include an active layer 307 disposed between a transparent conductive layer 309 and the bottom electrode 304. In such an embodiment, at least the first device 301 includes one or more electrical contacts 320 between the transparent conducting layer 309 and the backside top electrode 308. The electrical contacts 320 are formed through the transparent conducting layer 309, the active layer 307, the bottom electrode 304 and the insulating layer 306. The electrical contacts 320 provide an electrically conductive path between the transparent conducting layer 309 and the backside top electrode 308. The electrical contacts 320 are electrically isolated from the active layer 307, the bottom electrode 304 and the insulating layer 306.

The formation of good contacts between the conductive plug 324 and the substrate 308 may be assisted by the use of other interface-forming techniques such as ultrasonic welding. An example of a useful technique is the formation of gold stud-bumps, as described for example by J. Jay Wimer in “3-D Chip Scale with Lead-Free Processes” in Semiconductor International, Oct. 1, 2003, which is incorporated herein by reference. Ordinary solders or conductive inks or adhesives may be printed on top of the stud bump.

In forming the vias, it is important to avoid making shorting connections between the top electrode 309 and the bottom electrode 304. Therefore, mechanical cutting techniques such as drilling or punching may be advantageously supplemented by laser ablative removal of a small volume of material near the lip of the via, a few microns deep and a few microns wide. Some embodiments may use only laser removal processes. Alternatively, a chemical etching process may be used to remove the transparent conductor over a diameter slightly greater than the via. The etching can be localized, e.g., by printing drops of etchant in the appropriate places using inkjet printing or stencil printing.

A further method for avoiding shorts involves deposition of a thin layer of insulating material on top of the active layer 307 prior to deposition of the transparent conducting layer 309. This insulating layer is preferably several microns thick, and may be in the range of 1 to 100 microns. Since it is deposited only over the area where a via is to be formed (and slightly beyond the borders of the via), its presence does not interfere with the operation of the optoelectronic device. In some embodiments of the present invention, the layer may be similar to structures described in U.S. patent application Ser. No. 10/810,072 to Karl Pichler, filed Mar. 25, 2004, which is hereby incorporated by reference. When a hole is drilled or punched through this structure, there is a layer of insulator between the transparent conducting layer 309 and the bottom electrode 304 which may be relatively thick compared to these layers and to the precision of mechanical cutting processes, so that no short can occur.

The material for this layer can be any convenient insulator, preferably one that can be digitally (e.g. inkjet) printed. Thermoplastic polymers such as Nylon PA6 (melting point (m.p.) 223° C.), acetal (m.p. 165° C.), PBT (structurally similar to PET but with a butyl group replacing the ethyl group) (m.p. 217° C.), and polypropylene (m.p. 165° C.), are examples which by no means exhaust the list of useful materials. These materials may also be used for the insulating layer 322. While inkjet printing is a desirable way to form the insulator islands, other methods of printing or deposition (including conventional photolithography) are also within the scope of the invention.

In forming the vias, it is useful to fabricate the optoelectronic device in at least two initially separate elements, with one comprised of the insulating layer 306, the bottom electrode 304 and the layers 302 above it, and the second comprised of the back plane 308. These two elements are then laminated together after the vias have been formed through the composite structure 306/304/302, but before the vias are filled. After this lamination and via formation, the back plane 308 is laminated to the composite, and the vias are filled as described above.

Although jet-printed solders or conductive adhesives comprise useful materials for forming the conductive via plug 324, it is also possible to form this plug by mechanical means. Thus, for example, a wire of suitable diameter may be placed in the via, forced into contact with the back plane 308, and cut off at the desired height to form the plug 324, in a manner analogous to the formation of gold stud bumps. Alternatively a pre-formed pin of this size can be placed into the hole by a robotic arm. Such pins or wires can be held in place, and their electrical connection to the substrate assisted or assured, by the printing of a very thin layer of conductive adhesive prior to placement of the pin. In this way the problem of long drying time for a thick plug of conductive adhesive is eliminated. The pin can have tips or serrations on it which punch slightly into the back plane 308, further assisting contact. Such pins may be provided with insulation already present, as in the case of insulated wire or coated wire (e.g. by vapor deposition or oxidation). They can be placed in the via before the application of the insulating material, making it easier to introduce this material.

If the pin is made of a suitably hard metal, and has a slightly tapered tip, it may be used to form the via during the punching step. Instead of using a punch or drill, the pin is inserted into the composite 306/304/302, to a depth such that the tip just penetrates the bottom; then when the substrate 308 is laminated to this composite, the tip penetrates slightly into it and forms a good contact. These pins may be injected into the unpunched substrate by, for example, mechanical pressure or air pressure directed through a tube into which the pin just fits.

Fabricating the device modules 301, 311 on substrates S₁, S₂ made of relatively thick, highly conductive, flexible bulk conductor bottom electrodes 304, 314 and backplanes 308, 318 and forming insulated electrical contracts 320 through the transparent conducting layer 309, the active layer 330, the bottom electrodes 304, 314 and the insulating layer 306, 316 allows the device modules 301, 311 to be relatively large. Consequently the array 300 can be made of fewer device modules requiring fewer series interconnections compared to prior art arrays. For example, the device modules 301, 311 may be between about 1 centimeter and about 30 centimeters long and between about 1 and about 30 centimeters wide. Smaller cells (e.g., less than 1 centimeter long and/or 1 centimeter wide) may also be made as desired.

Note that since the back planes 308, 318 carry electric current from one device module to the next, the pattern of traces 326 need not contain thick busses, as used in the prior art for this purpose. Instead, the pattern of traces 326 need only provide sufficiently conductive “fingers” to carry current to the contacts 320. In the absence of busses, a greater portion of the active layers 302, 312 is exposed, which enhances efficiency. In addition, a pattern of traces 326 without busses can be more aesthetically pleasing.

Electrical contact between the back plane 308 of the first device module 301 and the bottom electrode 314 of the second device module 311 may be implemented by cutting back the back plane 318 and insulating layer 316 of the second device module to expose a portion of the bottom electrode 314. FIG. 6 illustrates an example of one way, among others, for cutting back the back plane 318 and insulating layer 316. Specifically, notches 317 may be formed in an edge of the insulating layer 316. The notches 317 align with similar, but slightly larger notches 319 in the back plane 318. The alignment of the notches 317, 319 exposes portions of the bottom electrode 314 of the second device module 311.

Electrical contact may be made between the back plane 308 of the first device module 301 and the exposed portion of the bottom electrode 314 of the second device module 311 in a number of different ways. For example, as shown in FIG. 6, thin conducting layer 328 may be disposed over a portion of the carrier substrate 303.

The thin conducting layer may be, e.g., a conductive (filled) polymer or silver ink. The conducting layer can be extremely thin, e.g., about 1 micron thick. A general criteria for determining the minimum thickness of the thin conducting layer 328 is that the fractional power p=(J/V) ρ (Lₒ²/d) dissipated in this layer is about 10⁻⁵ or less, where J is the current density, V is the voltage, Lₒ is the length of the thin conductive layer 328 (roughly the width of the gap between the first and second device modules) and ρ and d are respectively the resistivity and the thickness of the thin conductive layer 328. By way of numerical example, for many applications (J/V) is roughly 0.06 A/Vcm². If Lₒ=400 microns=0.04 cm then p is approximately equal to 10⁻⁴ (ρ/d). Thus, even if the resistivity ρ is about 10⁻⁵ Ωcm (which is about ten times less than for a good bulk conductor), d can be about 1 micron (10⁻⁴ cm) thick. Thus, even a relatively resistive polymer conductor of almost any plausible thickness will work.

Optionally, FIG. 7 shows that the layer 308 may be extended to reach an underside of layer 314 and make electrical contact by various methods including use of the conductive ink or epoxy or by use of a laser welding of layer 308 directly to layer 314.

Referring back to FIG. 6, the first device module 301 may be attached to the carrier substrate 303 such that the back plane 308 makes electrical contact with the thin conducting layer 328 while leaving a portion of the thin conducting layer 328 exposed. Electrical contact may then be made between the exposed portion of the thin conducting layer 328 and the exposed portion of the bottom electrode 314 of the second device module 311. For example, a bump of conductive material 329 (e.g., more conductive adhesive) may be placed on the thin conducting layer 328 at a location aligned with the exposed portion of the bottom electrode 314. The bump of conductive material 329 is sufficiently tall as to make contact with the exposed portion of the bottom electrode 314 when the second device module 311 is attached to the carrier substrate. The dimensions of the notches 317, 319 may be chosen so that there is essentially no possibility that the thin conducting layer 328 will make undesired contact with the back plane 318 of the second device module 311. For example, the edge of the bottom electrode 314 may be cut back with respect to the insulating layer 316 by an amount of cutback CB₁ of about 400 microns. The back plane 318 may be cut back with respect to the insulating layer 316 by an amount CB₂ that is significantly larger than CB₁.

The device layers 302, 312 are preferably of a type that can be manufactured on a large scale, e.g., in a roll-to-roll processing system. There are a large number of different types of device architectures that may be used in the device layers 302, 312. By way of example, and without loss of generality, the inset in FIG. 6 shows the structure of a CIGS active layer 307 and associated layers in the device layer 302. By way of example, the active layer 307 may include an absorber layer 330 based on materials containing elements of groups IB, IIIA and VIA. Preferably, the absorber layer 330 includes copper (Cu) as the group IB, Gallium (Ga) and/or Indium (In) and/or Aluminum as group IIIA elements and Selenium (Se) and/or Sulfur (S) as group VIA elements. Examples of such materials (sometimes referred to as CIGS materials) are described in U.S. Pat. No. 6,268,014, issued to Eberspacher et al on Jul. 31, 2001, and US Patent Application Publication No. US 2004-0219730 A1 to Bulent Basol, published Nov. 4, 2004, both of which are incorporated herein by reference. A window layer 332 is typically used as a junction partner between the absorber layer 330 and the transparent conducting layer 309. By way of example, the window layer 332 may include cadmium sulfide (CdS), zinc sulfide (ZnS), or zinc selenide (ZnSe) or some combination of two or more of these. Layers of these materials may be deposited, e.g., by chemical bath deposition or chemical surface deposition, to a thickness of about 50 nm to about 100 nm. A layer 334 of a metal different from the bottom electrode may be disposed between the bottom electrode 304 and the absorber layer 330 to inhibit diffusion of metal from the bottom electrode 304. For example, if the bottom electrode 304 is made of aluminum, the layer 334 may be a layer of molybdenum. This may help carry electrical charge and provide certain protective qualities. In addition, another layer 335 of material similar to that of layer 103 may also be applied between the layer 334 and the aluminum layer 304. The material may be the same as that of layer 103 or it may be another material selected from the set of material listed for layer 103. Optionally, another layer 337 also be applied to the other side of layer 304. The material may be the same as that of layer 335 or it may be another material selected from the set of material listed for layer 103. Protective layers similar to layers 335 and/or 337 may be applied around the foil on any of the embodiments described herein.

Although CIGS solar cells are described for the purposes of example, those of skill in the art will recognize that embodiments of the series interconnection technique can be applied to almost any type of solar cell architecture. Examples of such solar cells include, but are not limited to: cells based on amorphous silicon, Graetzel cell architecture (in which an optically transparent film comprised of titanium dioxide particles a few nanometers in size is coated with a monolayer of charge transfer dye to sensitize the film for light harvesting), a nanostructured layer having an inorganic porous semiconductor template with pores filled by an organic semiconductor material (see e.g., US Patent Application Publication US 2005-0121068 A1, which is incorporated herein by reference), a polymer/blend cell architecture, organic dyes, and/or C₆₀ molecules, and/or other small molecules, micro-crystalline silicon cell architecture, randomly placed nanorods and/or tetrapods of inorganic materials dispersed in an organic matrix, quantum dot-based cells, or combinations of the above. Furthermore, embodiments of the series interconnection technique described herein can be used with optoelectronic devices other than solar cells.

The transparent conductive layer 309 may be, e.g., a transparent conductive oxide (TCO) such as zinc oxide (ZnO) or aluminum doped zinc oxide (ZnO:Al), which can be deposited using any of a variety of means including but not limited to sputtering, evaporation, CBD, electroplating, CVD, PVD, ALD, and the like. Alternatively, the transparent conductive layer 309 may include a transparent conductive polymeric layer, e.g. a transparent layer of doped PEDOT (Poly-3,4-Ethylenedioxythiophene), which can be deposited using spin, dip, or spray coating, and the like. PSS:PEDOT is a doped, conducting polymer based on a heterocyclic thiophene ring bridged by a diether. A water dispersion of PEDOT doped with poly(styrenesulfonate) (PSS) is available from H. C. Starck of Newton, Mass. under the trade name of Baytron® P. Baytron® is a registered trademark of Bayer Aktiengesellschaft (hereinafter Bayer) of Leverkusen, Germany. In addition to its conductive properties, PSS:PEDOT can be used as a planarizing layer, which can improve device performance. A potential disadvantage in the use of PEDOT is the acidic character of typical coatings, which may serve as a source through which the PEDOT may chemically attack, react with, or otherwise degrade the other materials in the solar cell. Removal of acidic components in PEDOT may be carried out by anion exchange procedures. Non-acidic PEDOT can be purchased commercially. Alternatively, similar materials can be purchased from TDA materials of Wheat Ridge, Colo., e.g. Oligotron™ and Aedotron™.

The gap between the first device module 301 and the second device module 311 may be filled with a curable polymer epoxy, e.g., silicone. An optional encapsulant layer (not shown) may cover the array 300 to provide environmental resistance, e.g., protection against exposure to water or air. The encapsulant may also absorb UV-light to protect the underlying layers. Examples of suitable encapsulant materials include one or more layers of fluoropolymers such as THV (e.g. Dyneon's THV220 fluorinated terpolymer, a fluorothermoplastic polymer of tetrafluoroethylene, hexafluoropropylene and vinylidene fluoride), Tefzel® (DuPont), Tefdel, ethylene vinyl acetate (EVA), thermoplastics, polyimides, polyamides, nanolaminate composites of plastics and glasses (e.g. barrier films such as those described in commonly-assigned, co-pending U.S. Patent Application Publication US 2005-0095422 A1, to Brian Sager and Martin Roscheisen, entitled “INORGANIC/ORGANIC HYBRID NANOLAMINATE BARRIER FILM” which is incorporated herein by reference), and combinations of the above.

While the invention has been described and illustrated with reference to certain particular embodiments thereof, those skilled in the art will appreciate that various adaptations, changes, modifications, substitutions, deletions, or additions of procedures and protocols may be made without departing from the spirit and scope of the invention. For example, with any of the above embodiments, it should be understood that they are not limited to using some material layer between layer 150 and the absorber layer. Some embodiments may have one or more intervening layers. Other embodiments may have no additional material layers between the layer 150 and the back side of the absorber layer.

Furthermore, those of skill in the art will recognize that any of the embodiments of the present invention can be applied to almost any type of solar cell material and/or architecture. For example, the absorber layer in solar cell 10 may be an absorber layer comprised of silicon, amorphous silicon, copper-indium-gallium-selenium (for CIGS solar cells), CdSe, CdTe, Cu(In,Ga)(S,Se)₂, Cu(In,Ga,Al)(S,Se,Te)₂, (Cu,Au,Ag)(In,Ga,Al)(S,Se,Te)₂, Cu—In, In—Ga, Cu—Ga, Cu—In—Ga, Cu—In—Ga—S, Cu—In—Ga—Se, other absorber materials, II-VI materials, IB-VI materials, CuZnTe, CuTe, ZnTe, IB-IIB-IVA-VIA absorbers, or other alloys, and/or combinations of the above, where the active materials are present in any of several forms including but not limited to bulk materials, micro-particles, nano-particles, or quantum dots. The CIGS cells may be formed by vacuum or non-vacuum processes. The processes may be one stage, two stage, or multi-stage CIGS processing techniques. Additionally, other possible absorber layers may be based on amorphous silicon (doped or undoped), a nanostructured layer having an inorganic porous semiconductor template with pores filled by an organic semiconductor material (see e.g., US Patent Application Publication US 2005-0121068 A1, which is incorporated herein by reference), a polymer/blend cell architecture, organic dyes, and/or C₆₀ molecules, and/or other small molecules, micro-crystalline silicon cell architecture, randomly placed nanorods and/or tetrapods of inorganic materials dispersed in an organic matrix, quantum dot-based cells, or combinations of the above. Many of these types of cells can be fabricated on flexible substrates.

Additionally, concentrations, amounts, and other numerical data may be presented herein in a range format. It is to be understood that such range format is used merely for convenience and brevity and should be interpreted flexibly to include not only the numerical values explicitly recited as the limits of the range, but also to include all the individual numerical values or sub-ranges encompassed within that range as if each numerical value and sub-range is explicitly recited. For example, a size range of about 1 nm to about 200 nm should be interpreted to include not only the explicitly recited limits of about 1 nm and about 200 nm, but also to include individual sizes such as 2 nm, 3 nm, 4 nm, and sub-ranges such as 10 nm to 50 nm, 20 nm to 100 nm, etc. . . .

The publications discussed or cited herein are provided solely for their disclosure prior to the filing date of the present application. Nothing herein is to be construed as an admission that the present invention is not entitled to antedate such publication by virtue of prior invention. Further, the dates of publication provided may be different from the actual publication dates which may need to be independently confirmed. All publications mentioned herein are incorporated herein by reference to disclose and describe the structures and/or methods in connection with which the publications are cited. For example, U.S. Patent applications NSL-038 are NSL-092 are fully incorporated herein by reference for all purposes. U.S. Provisional Application Ser. No. 61/172,357 filed Apr. 24, 2009 and U.S. Provisional Application Ser. No. 61/185,559 filed Jun. 9, 2009 are fully incorporated herein by reference for all purposes.

Various aspects of the invention of the invention relating to the above are enumerated in the following paragraphs:

Aspect 1: A deposition method.

Aspect 2. The method of Aspect 1 comprising:

providing a substrate suitable for carrying electrical current;

individually controlling film characteristics for a material being simultaneously formed on both sides of the substrate so as to provide a first layer of the material on one side substantially thicker than a second layer on another side of the substrate, wherein material is electrically insulating but the second layer is configured to provide no substantial electrical resistance to current passing from the substrate through the second layer or vice versa.

Aspect 3. The method of Aspect 1 comprising:

shielding a cathode on at least one side of the substrate during deposition to create the second layer with thinner material thickness.

Aspect 4. The method of Aspect 3 comprising:

wherein the second layer has an average maximum thickness of about 50 nm or less.

Aspect 5. The method of Aspect 3 comprising:

wherein the second layer has an average minimum thickness sufficient so that the second layer is electrically conductive.

Aspect 6. The method of Aspect 1 wherein the material comprises of alumina, but the second layer is electrically conductive.

Aspect 7. The method of Aspect 1 wherein the second layer comprises of a plurality of pores, wherein the second layer has an overall maximum thickness of 50 nm to 100 nm and having an overall minimum thickness of at least 5 nm.

Aspect 8. The method of Aspect 1 wherein the substrate comprises of aluminum.

Aspect 9. The method of Aspect 1 wherein the material is electrically insulating, except when used in a configuration of the second layer, wherein the second layer is electrically conductive despite being comprised of the material that is electrically insulating.

Aspect 10. The method of Aspect 1 comprising forming an electrically insulating layer on one side of the substrate while an opposite side of the substrate remains electrically conductive without using masking on the opposite side.

Aspect 11. The method of Aspect 1 comprising immersing a substrate in a bath to form an electrically insulating layer on one side of the substrate while an opposite side of the substrate remains electrically conductive without using masking on the opposite side.

Aspect 12. The method of Aspect 1 comprising immersing a substrate in a bath to form an electrically insulating layer on one side of the substrate while simultaneously forming an electrically conductive layer on an opposite side of the substrate without masking the opposite side.

Aspect 13. The method of Aspect 1 further comprising sputtering a layer of an electronically conductive metal over the second layer.

Aspect 14. The method of claim 14 wherein a thickness of the layer of electronically conductive metal is less than 30 nm, optionally, 20 nm or less.

Aspect 15. The method of claim 14 wherein a thickness of the layer of electronically conductive metal is less than conventionally used.

Aspect 16. A solar cell comprising:

an aluminum substrate having an anodized electrically insulating backside layer and an anodized electrically conductive front side layer;

an electrically conductive layer over the anodized electrically conductive front side layer;

a thin-film photovoltaic absorber layer over the electrically conductive layer; and

a junction partner layer over the photovoltaic absorber layer.

Aspect 17. The solar cell of Aspect 17 wherein the anodized electrically conductive front side layer has a plurality of pores.

Aspect 18. The solar cell of Aspect 18 wherein the pores have a diameter of 30 to 200 nm.

Aspect 19. The solar cell of Aspect 18 wherein bottoms walls of the pores are at least 5 nm thick.

Aspect 20. A method comprising:

providing an electrically conductive elongate flexible substrate;

individually controlling film characteristics for a material being formed on both sides of the substrate so as to provide a first layer of the material on one side substantially thicker than a second layer on another side of the substrate, the second layer configured to provide low electrical resistance while the first layer is configured to provide high electrical resistance,

wherein the first layer and the second layer are formed simultaneously and comprise of the same material;

applying stress to the second layer to introduce additional defects into the second layer; and

filling these defects with electrically conductive material.

Optionally, the present invention provides a substrate with a first area that is provided with a first material and a second area that is provided with a second material, wherein the first and second materials are different from one another, and wherein the first and second materials are selected from one or more of the flowing (a) materials that promote mechanical strength with lower electrical conductivity, (b) materials having high electrical conductivity but soften at temperature of 520 C or higher, (c) materials that prevent chemical interdiffusion, (d), can grow a porous oxide theron, wherein the oxide bulk material has a bulk resistivity of 1000 ohm-cm. Optionally, the bulk resistivity is larger than about 10,000 ohm-cm. Optoinally, the material may be silicon dioxide.

While the above is a complete description of the preferred embodiment of the present invention, it is possible to use various alternatives, modifications and equivalents. Therefore, the scope of the present invention should be determined not with reference to the above description but should, instead, be determined with reference to the appended claims, along with their full scope of equivalents. Any feature, whether preferred or not, may be combined with any other feature, whether preferred or not. In the claims that follow, the indefinite article “A”, or “An” refers to a quantity of one or more of the item following the article, except where expressly stated otherwise. The appended claims are not to be interpreted as including means-plus-function limitations, unless such a limitation is explicitly recited in a given claim using the phrase “means for.”

What is claimed is:

1. A deposition method.

2. The method of claim 1 comprising:
providing a substrate suitable for carrying electrical current;
individually controlling film characteristics for a material being simultaneously formed on both sides of the substrate so as to provide a first layer of the material on one side substantially thicker than a second layer on another side of the substrate, wherein material is electrically insulating but the second layer is configured to provide no substantial electrical resistance to current passing from the substrate through the second layer or vice versa.

3. The method of claim 1 comprising:
shielding a cathode on at least one side of the substrate during deposition to create the second layer with thinner material thickness.

4. The method of claim 3 comprising:
wherein the second layer has an average maximum thickness of about 50 nm or less.

5. The method of claim 3 comprising:
wherein the second layer has an average minimum thickness sufficient so that the second layer is electrically conductive.

6. The method of claim 1 wherein the material comprises of alumina, but the second layer is electrically conductive.

7. The method of claim 1 wherein the second layer comprises of a plurality of pores, wherein the second layer has an overall maximum thickness of 50 nm to 100 nm and having an overall minimum thickness of at least 5 nm.

8. The method of claim 1 wherein the substrate comprises of aluminum.

9. The method of claim 1 wherein the material is electrically insulating, except when used in a configuration of the second layer, wherein the second layer is electrically conductive despite being comprised of the material that is electrically insulating.

10. The method of claim 1 comprising forming an electrically insulating layer on one side of the substrate while an opposite side of the substrate remains electrically conductive without using masking on the opposite side.

11. The method of claim 1 comprising immersing a substrate in a bath to form an electrically insulating layer on one side of the substrate while an opposite side of the substrate remains electrically conductive without using masking on the opposite side.

12. The method of claim 1 comprising immersing a substrate in a bath to form an electrically insulating layer on one side of the substrate while simultaneously forming an electrically conductive layer on an opposite side of the substrate without masking the opposite side.

13. The method of claim 1 further comprising sputtering a layer of an electronically conductive metal over the second layer.

14. The method of claim 14 wherein a thickness of the layer of electronically conductive metal is less than 25 nm.

15. The method of claim 14 wherein a thickness of the layer of electronically conductive metal is less than conventionally used.

16. A solar cell comprising:
an aluminum substrate having an anodized electrically insulating backside layer and an anodized electrically conductive front side layer;
an electrically conductive layer over the anodized electrically conductive front side layer;
a thin-film photovoltaic absorber layer over the electrically conductive layer; and
a junction partner layer over the photovoltaic absorber layer.

17. The solar cell of claim 17 wherein the anodized electrically conductive front side layer has a plurality of pores.

18. The solar cell of claim 18 wherein the pores have a diameter of 5 nm to 100 nm.

19. The solar cell of claim 18 wherein bottoms walls of the pores are at least 5 nm thick.

20. A method comprising:
providing an electrically conductive elongate flexible substrate;
individually controlling film characteristics for a material being formed on both sides of the substrate so as to provide a first layer of the material on one side substantially thicker than a second layer on another side of the substrate, the second layer configured to provide low electrical resistance while the first layer is configured to provide high electrical resistance,
wherein the first layer and the second layer are formed simultaneously and comprise of the same material;
applying stress to the second layer to introduce additional defects into the second layer; and
filling these defects with electrically conductive material.
